(19) United States
(12) Patent Application Publication
(10) Pub. No.: US 2026/0215272 A1
(43) Pub. Date: Jul. 23, 2026

(54) SEMICONDUCTOR MODULE AND SEMICONDUCTOR DEVICE

(71) Applicant: FUJI ELECTRIC CO., LTD., Kawasaki-shi (JP)

(72) Inventors: Takahiro KOYAMA, Kawasaki-shi (JP); Kensuke MATSUZAWA, Kawasaki-shi (JP); Hiromichi GOHARA, Kawasaki-shi (JP)

(73) Assignee: FUJI ELECTRIC CO., LTD., Kawasaki-shi (JP)

(21) Appl. No.: 19/570,557

(22) Filed: Mar. 18, 2026

Related U.S. Application Data
(63) Continuation of application No. PCT/JP2025/009769, filed on Mar. 14, 2025.

(30) Foreign Application Priority Data
Apr. 23, 2024 (JP) 2024-069640

(51) Int. Cl. H10W 40/47; H10W 40/20; H10W 40/22

(52) U.S. Cl. CPC H10W 40/47; H10W 40/228; H10W 40/235

(57) ABSTRACT

A semiconductor module for use in a semiconductor device having a water jacket. The semiconductor module includes: a substrate; a semiconductor element mounted on the substrate; a cooler that has a heat dissipation base, and a plurality of heat dissipation fins positioned on the heat dissipation base, on a side thereof opposite to the substrate, the cooler being configured to be attached to the water jacket for allowing cooling water to flow in a flow direction through the plurality of heat dissipation fins; and an insulating material integrally forming a bottom portion that extends along the flow direction, and faces tips of at least a first subset of the plurality of heat dissipation fins, and a sidewall that extends from the bottom portion toward the heat dissipation base, and faces at least a second subset of the plurality of heat dissipation fins.

### CROSS-REFERENCE TO RELATED APPLICATIONS

This is a continuation application of International Application PCT/JP2025/009769 filed on Mar. 14, 2025 which claims priority from a Japanese Patent Application No. 2024-069640 filed on Apr. 23, 2024, the contents of which are incorporated herein by reference.

### TECHNICAL FIELD

The present invention relates to a semiconductor module including a cooler, and a semiconductor device including the semiconductor module and a water jacket.

### BACKGROUND ART

Among semiconductor devices used for power conversion devices such as inverter devices, there are known semiconductor devices in which cooling water flows through a plurality of heat dissipation fins in a water jacket in order to cool a semiconductor element by heat dissipation (for example, see Patent Literatures 1 to 4). A clearance is provided between the plurality of heat dissipation fins and the water jacket in order to avoid contact between the plurality of heat dissipation fins and the water jacket due to variations in dimensions at the time of manufacture.

### CITATION LIST

### Patent Literature

Patent Literature 1: JP 7160216 B2
Patent Literature 2: WO 2012/114475 A
Patent Literature 3: WO 2014/045758 A
Patent Literature 4: JP 2007-110025 A

### SUMMARY OF INVENTION

### Technical Problem

The larger the clearance between the plurality of heat dissipation fins and the water jacket, the less cooling water passes through spaces between the heat dissipation fins, resulting in deterioration in cooling performance. In addition, in the clearance, a local battery due to a potential difference is formed, and a corrosion product is generated. The cooling performance also deteriorates due to the corrosion product clogging the spaces between the heat dissipation fins. However, in a case where the member closing the clearance is fixed or positioned, assembling the semiconductor device is time-consuming.

An object of the present invention is to provide a semiconductor module and a semiconductor device that can be easily assembled while improving cooling performance and preventing corrosion.

### Solution to Problem

In one aspect, a semiconductor module includes a semiconductor element, a substrate, a cooler, and an insulating material. The semiconductor element is mounted on the substrate. The cooler has a heat dissipation base and a plurality of heat dissipation fins positioned on a side opposite to the substrate from the heat dissipation base, and is attached to a water jacket for allowing cooling water to flow through the plurality of heat dissipation fins. The insulating material integrally has a bottom portion that extends along a flow direction in which the cooling water flows through the plurality of heat dissipation fins, and faces at least some of tips of the plurality of heat dissipation fins, and a sidewall that extends from the bottom portion toward the heat dissipation base, and faces at least some of the plurality of heat dissipation fins.

### Advantageous Effects of Invention

According to the aspect, in a semiconductor module and a semiconductor device, it is possible to make assembly easy while improving cooling performance and preventing corrosion.

### BRIEF DESCRIPTION OF DRAWINGS

FIG. 1 is a right side view of a semiconductor device showing an internal structure of a water jacket in one embodiment.

FIG. 2 is an exploded perspective view of a cooler, an insulating material, and the water jacket in the embodiment.

FIG. 3 is a front view of the semiconductor device showing the internal structure of the water jacket in the embodiment.

FIG. 4 is a cross-sectional view taken along line IV-IV of FIG. 3.

FIG. 5A is a cross-sectional view taken along line IV-IV of FIG. 3 in a first modification of the embodiment.

FIG. 5B is a graph showing a relationship between an installation size of the insulating material and a pressure loss.

FIG. 6 is a cross-sectional view taken along line IV-IV of FIG. 3 in a second modification of the embodiment.

FIG. 7 is a cross-sectional view taken along line IV-IV of FIG. 3 in a third modification of the embodiment.

FIG. 8 is a cross-sectional view taken along line IV-IV of FIG. 3 in a fourth modification of the embodiment.

FIG. 9 is a right side view of a semiconductor device showing an internal structure of a water jacket in a fifth modification of the embodiment.

FIG. 10 is a cross-sectional view taken along line IV-IV of FIG. 3 in the fifth modification of the embodiment.

FIG. 11 is a right side view of a semiconductor device showing an internal structure of a water jacket in a sixth modification of the embodiment.

FIG. 12 is a right side view of the semiconductor device showing the internal structure of the water jacket in a state in which the insulating material is removed.

FIG. 13 is a front view of the semiconductor device showing the internal structure of the water jacket in a state in which the insulating material is removed.

FIG. 14 is a cross-sectional view taken along line XIV-XIV of FIG. 13.

FIG. 15 is an explanatory view for explaining the generation of a corrosion product.

FIG. 16 is a front view of the semiconductor device showing the internal structure of the water jacket for explaining a corroded portion in a state in which the insulating material is removed.

### DESCRIPTION OF EMBODIMENTS

Hereinafter, a semiconductor module and a semiconductor device according to one embodiment of the present invention will be described with reference to the drawings. The present invention is not limited to the embodiments described below, and can be appropriately modified and implemented within the scope not changing the gist thereof.

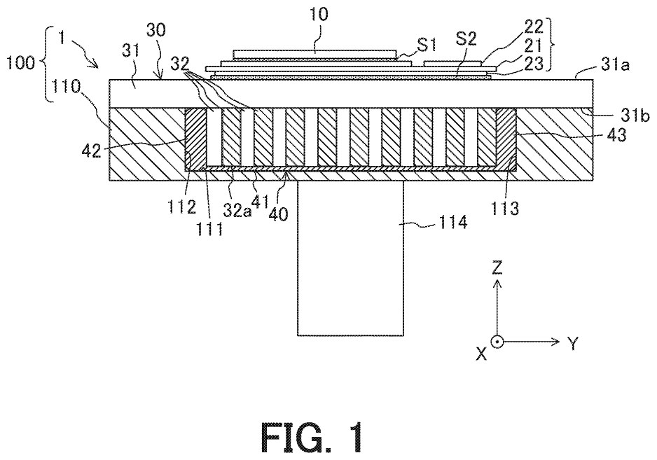

FIG. 1 is a right side view of a semiconductor device 100 showing an internal structure of a water jacket 110 in one embodiment.

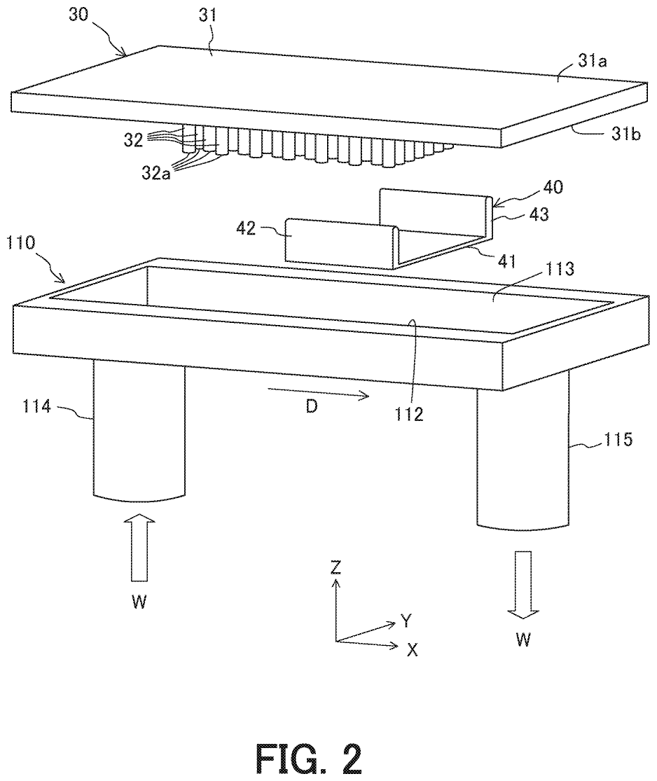

FIG. 2 is an exploded perspective view of a cooler 30, an insulating material 40, and the water jacket 110.

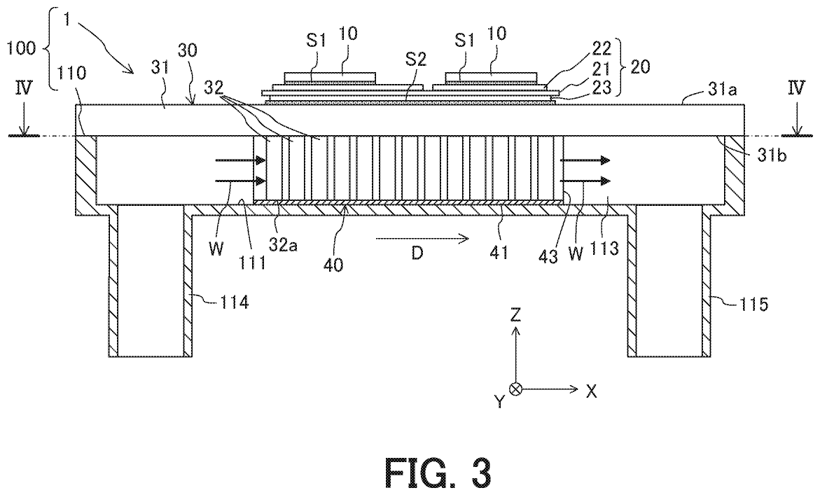

FIG. 3 is a front view of the semiconductor device 100 showing the internal structure of the water jacket 110.

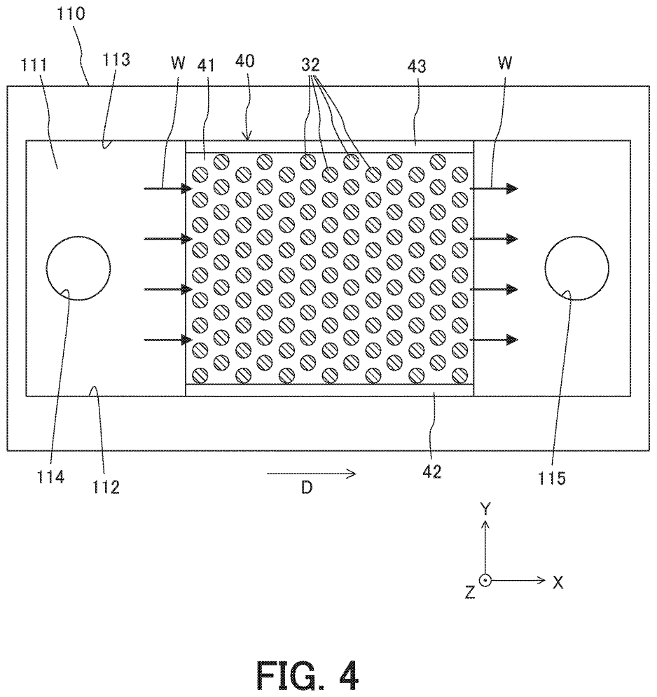

FIG. 4 is a cross-sectional view taken along line IV-IV of FIG. 3.

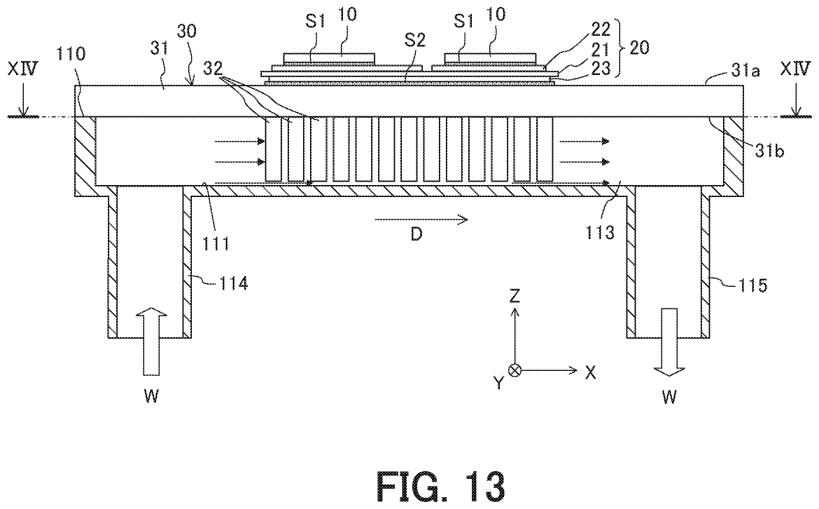

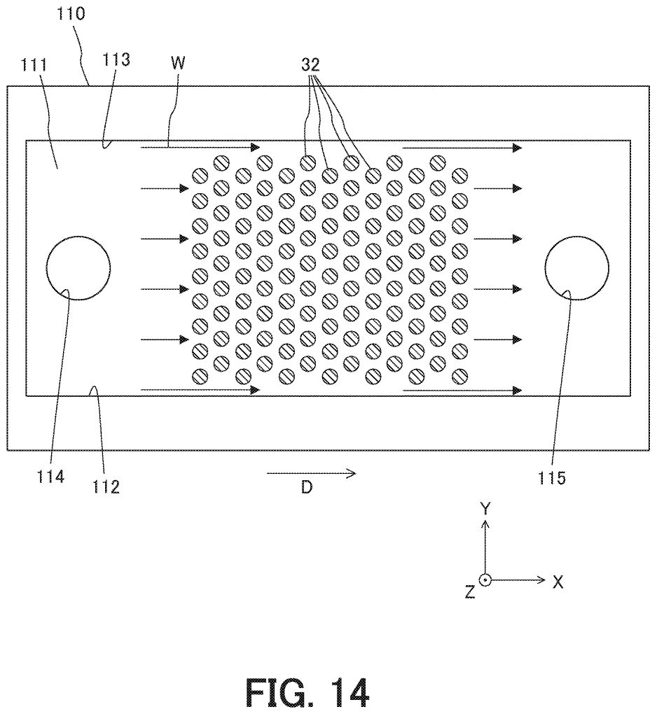

Regarding an X direction, a Y direction, and a Z direction shown in FIGS. 1 to 4 and FIGS. 5A, 6 to 14, and 16 to be described later, a thickness direction of a semiconductor element 10 is defined as the Z direction, and in the X direction and the Y direction that are orthogonal to the Z direction and are orthogonal to each other, a flow direction D of cooling water W is defined as the positive X direction. Furthermore, in some cases, the X direction may be referred to as a right-left direction, the Y direction may be referred to as a front-rear direction, and the Z direction may be referred to as an up-down direction. Such directional terms are used for convenience of description. Thus, depending on the attachment posture of the semiconductor device 100, the correspondence relationships between the X direction, the Y direction, and the Z direction will vary.

A semiconductor module 1 according to the present embodiment is applied, for example, to a power conversion device such as a power control unit, and serves as a power semiconductor module constituting an inverter circuit. The semiconductor module 1 and the semiconductor device 100 including the semiconductor module 1 and the water jacket 110 are applied for any purpose, and used, for example, as an inverter device of an on-vehicle or industrial motor.

The semiconductor device 100 shown in FIGS. 1 and 3 includes the semiconductor module 1 and the water jacket 110. The semiconductor module 1 includes two semiconductor elements 10, a stacked substrate 20, a cooler 30, and an insulating material 40.

The water jacket 110 is attached to a lower portion of the cooler 30 by, for example, fastening a screw. The water jacket 110 is provided, for example, in an inverter case of the inverter device. A sealing material such as an O-ring may be disposed between an upper surface of the water jacket 110 and the cooler 30 (heat dissipation base 31) from the viewpoint of ensuring water tightness inside the water jacket 110.

The water jacket 110 is made of, for example, a die-casting material such as an aluminum alloy (ADC12). The water jacket 110 has a rectangular parallelepiped shape that is open at an upper portion thereof, and the cooling water W flows inside the water jacket 110 that accommodates a plurality of heat dissipation fins 32. The cooling water W flows in the flow direction D in the right direction (in the positive X direction) so as to pass through the plurality of heat dissipation fins 32 of the cooler 30, and heat is transferred from the plurality of heat dissipation fins 32 to the cooling water W. The cooling water W is, for example, a liquid such as water containing additives, such as antifreeze agents, rust inhibitors, and antioxidants.

A bottom surface 111 inside the water jacket 110 through which the cooling water W flows faces tips 32a of the plurality of heat dissipation fins 32 via the insulating material 40. Front and rear side surfaces 112 and 113 inside the water jacket 110 expand in the XZ plane, and therefore extend along the flow direction D (in the positive X direction) in which the cooling water W flows through the plurality of heat dissipation fins 32. In the present embodiment, the flow direction D is parallel to a longitudinal direction (X direction) of the region where the plurality of heat dissipation fins 32 are disposed in plan view (see FIG. 4), but may be parallel to a lateral direction (Y direction).

As shown in FIGS. 2 and 3, an introduction pipe 114 for introducing the cooling water W into the water jacket 110 and a discharge pipe 115 for discharging the cooling water W from the water jacket 110 are connected to the bottom surface 111 of the water jacket 110. The introduction pipe 114 and the discharge pipe 115 extend downward (in the negative Z direction) from the bottom surface 111. However, the introduction pipe 114 and the discharge pipe 115 may extend in the X direction or the Y direction.

The two semiconductor elements 10 of the semiconductor module 1 are mounted on the stacked substrate 20 (circuit board 22) by a bonding material S1 which is, for example, solder, and are connected to another circuit board by a conductor wire, a metal wiring board, or the like. For example, the semiconductor element 10 is formed of a semiconductor substrate made of silicon (Si), silicon carbide (SiC), gallium nitride (GaN), or diamond, which has a square or rectangular shape in plan view.

As the semiconductor element 10, a switching element such as an insulated gate bipolar transistor (IGBT) and a power metal oxide semiconductor field effect transistor (power MOSFET), and a diode such as a freewheeling diode (FWD) are used. The switching element and the diode may be connected in anti-parallel. In addition, as the semiconductor element 10, used may be a reverse conducting (RC)-IGBT element in which an IGBT and an FWD are integrated into a single unit, a power MOSFET element, or a reverse blocking (RB)-IGBT having a sufficient breakdown voltage against reverse bias.

The stacked substrate 20 is an example of a substrate on which the semiconductor element 10 is mounted. The stacked substrate 20 is formed of, for example, a direct copper bonding (DCB) substrate, an active metal brazing (AMB) substrate, or a metal-based substrate. The stacked substrate 20 is formed in, for example, a rectangular shape in plan view. The stacked substrate 20 has an insulating plate 21, a circuit board 22, and a heat dissipation plate 23.

For example, the insulating plate 21 is made of an insulating material such as a ceramic material such as aluminum oxide (Al₂O₃), aluminum nitride (AlN), silicon nitride (Si₃N₄), or a composite material of aluminum oxide and zirconium oxide (ZrO₂), a resin material such as epoxy, or an epoxy resin material using a ceramic material as a filler. The insulating plate 21 may be referred to as an insulating layer or an insulating film.

The circuit board 22 is formed on an upper surface of the insulating plate 21. The number of the circuit boards 22 may be any number of one or more. The circuit board 22 is a metal layer such as copper foil, and for example, a plurality of the circuit boards 22 are formed like islands in a mutually electrically insulated state on the insulating plate 21. The circuit board 22 may be referred to as a circuit pattern, a circuit layer, a wiring board, a wiring pattern, a wiring layer, or the like.

The heat dissipation plate 23 is formed on a lower surface of the insulating plate 21. The heat dissipation plate 23 may be formed of a metal plate having good thermal conductivity, such as copper or aluminum, for example. The heat dissipation plate 23 is bonded to an upper surface 31a of the heat dissipation base 31 of the cooler 30 by a bonding material S2 which is, for example, solder. The heat dissipation plate 23 may be referred to as a heat dissipation layer or the like.

Although the two semiconductor elements 10 and the stacked substrate 20 described above are disposed on the upper portion of the heat dissipation base 31, for example, three sets of semiconductor units forming a three-phase inverter circuit may be disposed by using the two semiconductor elements 10 and the stacked substrates 20 as one set of semiconductor units. As described above, the number of the semiconductor elements 10 and the stacked substrates 20 is not particularly limited.

A case made of a rectangular frame-shaped resin may be disposed on the upper portion of the heat dissipation base 31 to surround the two semiconductor elements 10 and the stacked substrate 20, and the case may be filled with a sealing material (for example, resin or gel) to cover the two semiconductor elements 10 and the stacked substrate 20. The sealing material may be formed by transfer molding or potting.

The cooler 30 has the heat dissipation base 31 and the plurality of heat dissipation fins 32. The cooler 30 is made of, for example, a copper material or an aluminum material.

The heat dissipation base 31 has, for example, a rectangular plate shape. As described above, the stacked substrate 20 (heat dissipation plate 23) is bonded to the upper surface 31a, which is an example of the first surface of the heat dissipation base 31, by the bonding material S2. The heat dissipation base 31 can be referred to as a top plate of the cooler 30. The stacked substrate 20 may be bonded to the upper surface 31a of the heat dissipation base 31 via, for example, a flat plate for heat dissipation or the like.

The plurality of heat dissipation fins 32 protrude from a lower surface 31b, which is an example of the second surface of the heat dissipation base 31. As a result, the plurality of heat dissipation fins 32 are positioned on the side opposite to the stacked substrate 20 (in the negative Z direction) from the heat dissipation base 31. In addition, the heat dissipation fins 32 can be said to be open fins exposed to the outside of the cooler 30 below the heat dissipation base 31. The plurality of heat dissipation fins 32 may be formed to be integrated with the heat dissipation base 31, or may be formed by being fixed to the heat dissipation base 31. The plurality of heat dissipation fins 32 are, for example, pin fins and each have a cylindrical shape as shown in FIG. 4. The plurality of heat dissipation fins 32 are arranged in both of the X direction and the Y direction. Since the heat exchange performance of the plurality of heat dissipation fins 32 increases as the flow velocity of the cooling water W passing through the heat dissipation fins 32 increases, the density and the arrangement of the heat dissipation fins 32 are designed in consideration of the balance with the allowable pressure of a pump circulating the cooling water W.

The plurality of heat dissipation fins 32 are not limited to cylindrical pin fins, but may be pin fins having other shapes such as a polygonal column shape, flat plate-shaped fins (plate fins), curved plate-shaped fins (corrugated fins), or the like, and are not particularly limited.

The insulating material 40 integrally has a bottom portion (bottom wall) 41 and sidewalls 42 and 43 facing each other, and its overall shape is a U-plate shape in right side view (see FIG. 1). The insulating material 40 may be made of, for example, an elastic body such as silicone rubber or ethylene propylene rubber. The insulating material 40 made of an elastic body makes assembly, such as attachment of the insulating material 40 to the cooler 30 and subsequent mounting of the semiconductor module 1 on the water jacket 110, or prior placement of the insulating material 40 on the water jacket 110 followed by mounting of the cooler 30 on the insulating material 40, particularly easy. The insulating material 40 may be disposed by applying a liquid paste or the like to the water jacket 110. In addition, the insulating material 40 may be fixed to the cooler 30 or the water jacket 110 by adhesion or the like.

As shown in FIG. 1, the bottom portion 41 of the insulating material 40 is disposed on at least a part of the bottom surface 111 inside the water jacket 110, and has a flat plate shape. In addition, the bottom portion 41 extends along the flow direction D in which the cooling water W flows through the plurality of heat dissipation fins 32, and is disposed to face at least some of the tips 32a of the plurality of heat dissipation fins 32. As shown in FIG. 4, the bottom portion 41 may be disposed on the bottom surface 111 of the water jacket 110 to face the tips 32a of all the heat dissipation fins 32. That is, the bottom portion 41 may be formed to have a size equal to or larger than that of the region where the plurality of heat dissipation fins 32 are disposed in both of the X direction and the Y direction.

In a case where the plurality of heat dissipation fins 32 extend downward (in the negative Z direction) due to thermal expansion, the bottom portion 41 may be made of an elastic body as described above in order to suppress impairment in sealing performance between the cooler 30 and the water jacket 110 and deformation of the heat dissipation fins 32 due to the plurality of heat dissipation fins 32 (cooler 30) being pushed upward by the bottom portion 41. The thermal expansion may not only cause the heat dissipation fins 32 to extend in the negative Z direction, but also cause the heat dissipation fins 32 to extend in the X and Y directions and the water jacket 110 to extend toward the heat dissipation fins 32. Therefore, the entire insulating material 40 may be made of an elastic body as described above, and may follow the thermal deformation of the plurality of heat dissipation fins 32 and the water jacket 110.

The sidewall 42 (first sidewall) is disposed on at least a part of the side surface 112, which is the front surface inside the water jacket 110, and has a flat plate shape. In addition, the sidewall 43 (second sidewall) is disposed on at least a part of the side surface 113, which is the rear surface inside the water jacket 110, and has a flat plate shape. The sidewalls 42 and 43 extend from the bottom portion 41 toward the heat dissipation base (in the positive Z direction), and are disposed to face at least some of the heat dissipation fins. As shown in FIG. 4, the sidewalls 42 and 43 may be formed to have a size equal to or larger than that of the region where the plurality of heat dissipation fins 32 are disposed in the X direction. In addition, as shown in FIG. 3, the sidewalls 42 and 43 may be formed at the same height as the plurality of heat dissipation fins 32 in the Z direction.

The plurality of heat dissipation fins 32 are surrounded by the bottom portion 41 and the sidewalls 42 and 43 of the insulating material 40. The thickness (Z direction) of the bottom portion 41 may coincide with a clearance between the plurality of heat dissipation fins 32 and the bottom surface 111 of the water jacket 110 at a temperature before heat generation of the semiconductor element 10. In addition, the thicknesses (Y direction) of the sidewalls 42 and 43 may coincide with clearances between the plurality of heat dissipation fins 32 and the side surfaces 112 and 113 of the water jacket 110 at a temperature before heat generation of the semiconductor element 10. With this configuration, the clearance between the heat dissipation fins 32 and the water jacket 110 can be filled with the insulating material 40. In the example of FIG. 1, since the clearances between the plurality of heat dissipation fins 32 and the side surfaces 112 and 113 of the water jacket 110 are larger than the clearance between the plurality of heat dissipation fins 32 and the bottom surface 111 of the water jacket 110, the thicknesses of the sidewalls 42 and 43 are larger than the thickness of the bottom portion 41.

At least one of the bottom portion 41, the sidewall 42, and the sidewall 43 may have a thickness that is partially increased or decreased. For example, the thicknesses of the bottom portion 41 and the sidewalls 42 and 43 may be partially increased so that the cooling water W easily passes through spaces between some heat dissipation fins 32 by further narrowing the clearance between the heat dissipation fins 32 and the water jacket 110, or conversely, the thickness of the bottom portion 41 may be partially decreased below the heat dissipation fins 32 that become hot and easily extend downward (in the negative Z direction) due to thermal expansion.

In addition, the insulating material 40 may have an L-plate shape having a bottom portion 41 and a sidewall 42 or 43. In addition, an L-plate-shaped insulating material having a part of the bottom portion 41 in the negative Y direction and the sidewall 42 and an L-plate-shaped insulating material having a part of the bottom portion 41 in the positive Y direction and the sidewall 43 may be disposed.

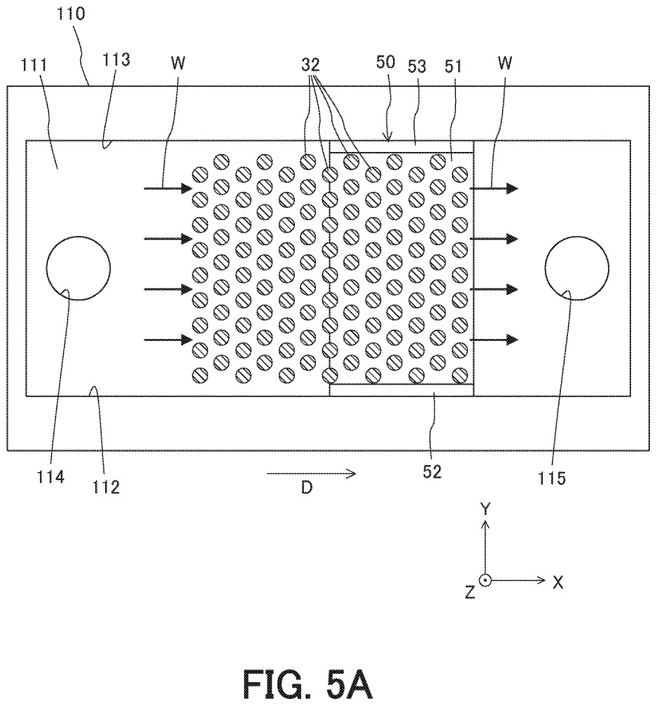

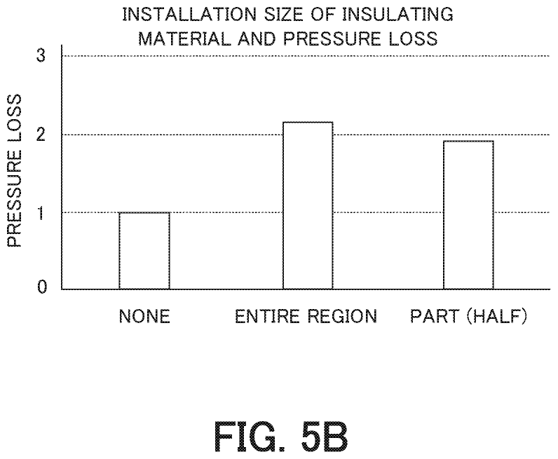

FIG. 5A is a cross-sectional view taken along line IV-IV of FIG. 3 in a first modification (cross-sectional view corresponding to FIG. 4).

As shown in FIG. 5A, similarly to the above-described insulating material 40, an insulating material 50 in the first modification integrally has a bottom portion 51 and sidewalls 52 and 53 facing each other.

Since the cooling water W flows through the plurality of heat dissipation fins 32, the temperature of the cooling water W is likely to be higher when the cooling water W passes through the heat dissipation fins 32 on the downstream side in the flow direction D than when the cooling water W passes through the heat dissipation fins 32 on the upstream side in the flow direction D. Therefore, from the viewpoint of making the heat dissipation performance uniform between the heat dissipation fins 32 on the upstream side in the flow direction D and the heat dissipation fins 32 on the downstream side in the flow direction D, it is desirable to fill the clearance between the heat dissipation fins 32 and the water jacket 110 only on the downstream side in the flow direction D, thereby making the flow rate (flow velocity) of the cooling water W passing through the heat dissipation fins 32 greater on the downstream side than on the upstream side in the flow direction D. Therefore, the insulating material 50 is disposed only in a downstream side part of the region where the heat dissipation fins 32 are disposed in the flow direction D (in the positive X direction). The insulating material 50 shown in FIG. 5A is an example in which a length in the X direction is half of the length of the insulating material 40 shown in FIG. 4.

As shown in FIG. 5B, when a pressure loss in a case where the insulating material 40 is not disposed is set to “1”, a pressure loss of the insulating material 40 (the entire region where the plurality of heat dissipation fins 32 are disposed) shown in FIG. 4 exceeds “2”, but a pressure loss of the insulating material 50 (half that is a downstream side part of the region where the plurality of heat dissipation fins 32 are disposed) shown in FIG. 5A is less than “2”. Therefore, it can be said that the insulating material 50 can reduce the pressure loss more than the insulating material 40 while uniformizing the heat dissipation performance in the downstream side part of the region where the plurality of heat dissipation fins 32 are disposed.

Since matters other than those described in the first modification can be the same as those in the above description, overlapping matters will not be described. Similarly, in second to sixth modifications to be described later, overlapping matters will not be described.

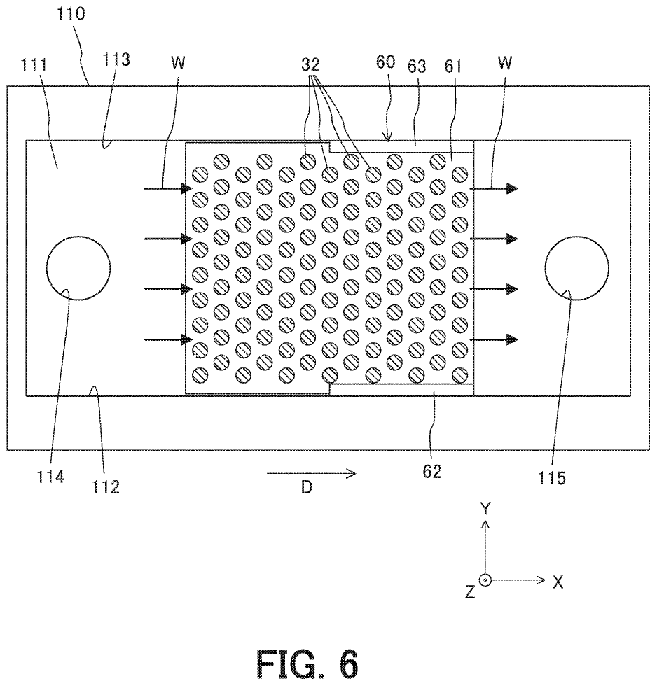

FIG. 6 is a cross-sectional view taken along line IV-IV of FIG. 3 in a second modification (cross-sectional view corresponding to FIG. 4).

As shown in FIG. 6, similarly to the above-described insulating materials 40 and 50, an insulating material 60 in the second modification integrally has a bottom portion 61 and sidewalls 62 and 63 facing each other.

In a case of the insulating material 60 shown in FIG. 6, unlike the insulating material 50 shown in FIG. 5A, the entire insulating material 60 is not disposed only in a downstream side part of the region where the plurality of heat dissipation fins 32 are disposed, but only the sidewalls 62 and 63 are disposed only in the downstream side part of the region where the plurality of heat dissipation fins 32 are disposed. That is, the sidewalls 62 and 63 are positioned to face only some heat dissipation fins 32 on the downstream side in the flow direction D among the plurality of heat dissipation fins 32.

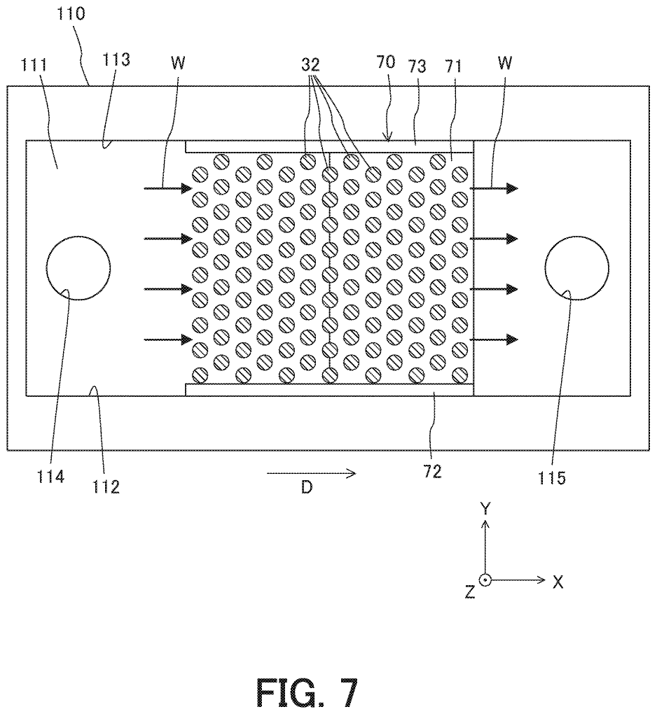

FIG. 7 is a cross-sectional view taken along line IV-IV of FIG. 3 in a third modification (cross-sectional view corresponding to FIG. 4).

As shown in FIG. 7, similarly to the above-described insulating materials 40, 50, and 60, an insulating material 70 in the third modification integrally has a bottom portion 71 and sidewalls 72 and 73 facing each other.

In a case of the insulating material 70 shown in FIG. 7, unlike the insulating material 50 shown in FIG. 5A, the entire insulating material 70 is not disposed only in a downstream side part of the region where the plurality of heat dissipation fins 32 are disposed, but only the bottom portion 71 is disposed only in the downstream side part of the region where the plurality of heat dissipation fins 32 are disposed. That is, the bottom portion 71 is positioned to face the tips 32a of only some heat dissipation fins 32 on the downstream side in the flow direction D among the plurality of heat dissipation fins 32.

In a case where the semiconductor element 10 is positioned above only the heat dissipation fins 32 at the center part in the flow direction D, it is desirable to relatively enhance the heat dissipation performance of the heat dissipation fins 32 at the center part in the flow direction D. In this case, of the above-described entire insulating material 50, sidewalls 62 and 63 of the insulating material 60, and bottom portion 71 of the insulating material 70, each portion provided to face only some heat dissipation fins 32 may be disposed only in the region where the heat dissipation fins 32 at the center part in the flow direction D are disposed.

In addition, in a case where the two semiconductor elements 10 are positioned on the upstream side and the downstream side in the flow direction D and the heat dissipation performance of the heat dissipation fins 32 below each of the two semiconductor elements 10 is enhanced, as in a case of the insulating material 50 shown in FIG. 5A, the insulating material 50 facing only some heat dissipation fins 32 may be disposed below each of the two semiconductor elements 10. In this manner, a plurality of the insulating materials 50 may be disposed at intervals in the flow direction D.

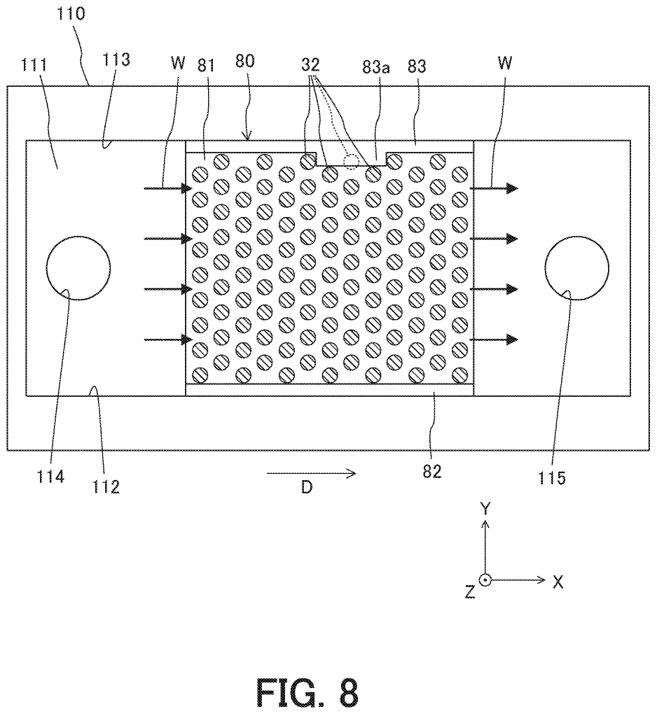

FIG. 8 is a cross-sectional view taken along line IV-IV of FIG. 3 in a fourth modification (cross-sectional view corresponding to FIG. 4).

As shown in FIG. 8, the plurality of heat dissipation fins 32 are arranged at equal intervals in the X direction and the Y direction, but one heat dissipation fin 32 positioned at an end portion in the positive Y direction is lacking (the missing heat dissipation fin 32 is indicated by the broken lines). Therefore, it can be considered that a recess portion is formed in the plurality of heat dissipation fins 32 in plan view (see FIG. 8). The plurality of heat dissipation fins 32 are disposed in a zig-zag manner so that the heat dissipation fins 32 whose positions in the Y direction are shifted by a half of the arrangement interval between the heat dissipation fins 32 are alternately arranged in the X direction, but the arrangement intervals in both of the X direction and the Y direction are constant.

Similarly to the above-described insulating material 40, an insulating material 80 integrally has a bottom portion 81 and sidewalls 82 and 83 facing each other. The sidewall 83 is provided with a fin side protrusion portion 83a protruding toward the plurality of heat dissipation fins 32. The fin side protrusion portion 83a is inserted into the recess portion (a portion where one heat dissipation fin 32 is lacking) of the plurality of heat dissipation fins 32 described above. Desirably, the fin side protrusion portion 83a is fitted into the recess portion of the plurality of heat dissipation fins 32. The fin side protrusion portion 83a is formed at the same height as the plurality of heat dissipation fins 32 (that is, at the same height as the sidewall 83) in the Z direction, but may protrude from a part of the sidewall 83 in the Z direction toward the plurality of heat dissipation fins 32 at a height lower than the plurality of heat dissipation fins 32, the recess portion of the plurality of heat dissipation fins 32, or the sidewall 83. The recess portion of the plurality of heat dissipation fins 32 may be formed by, for example, shortening the length of the heat dissipation fin 32 at an end portion in the positive Y direction or an end portion in the negative Y direction, or cutting out a part of the end portion in the positive Y direction of the heat dissipation fin 32 at the end portion in the positive Y direction or a part of the end portion in the negative Y direction of the heat dissipation fin 32 at the end portion in the negative Y direction.

In the fourth modification, the fin side protrusion portion 83a is provided only on the sidewall 83 of the insulating material 80. However, the fin side protrusion portion may be provided only on the sidewall 82, or the fin side protrusion portion 83a may be provided on both of the sidewalls 82 and 83.

In addition, a fin side recess portion may be provided in the insulating material 80, and a protrusion portion that is inserted into the fin side recess portion may be provided in the plurality of heat dissipation fins 32. In this case, the protrusion portion of the plurality of heat dissipation fins 32 may be provided to protrude, for example, in the Y direction from at least one heat dissipation fin 32, or may be provided by placing an additional heat dissipation fin 32.

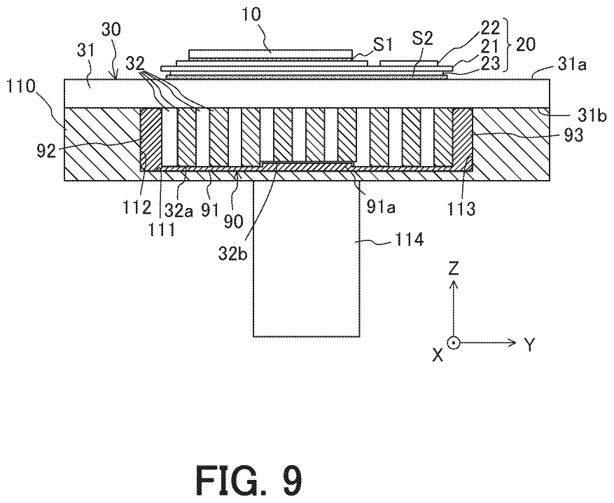

FIG. 9 is a right side view of a semiconductor device showing an internal structure of a water jacket 110 in a fifth modification.

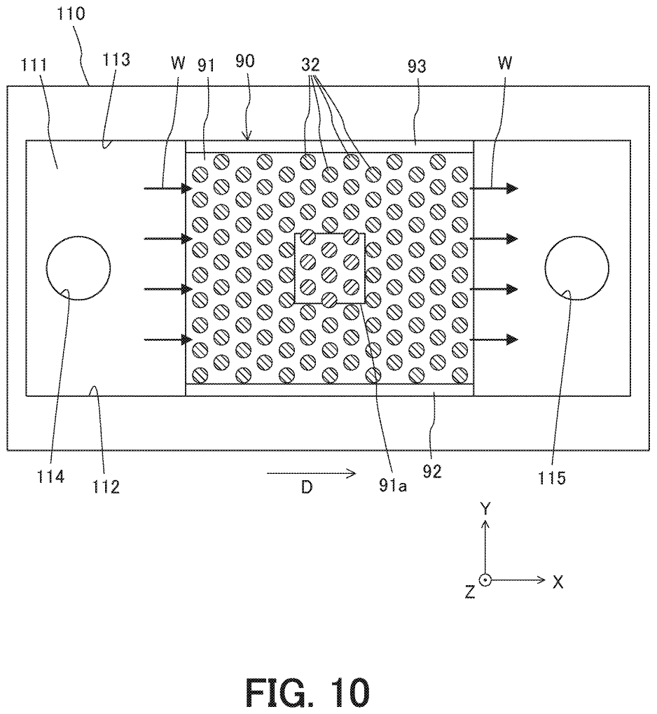

FIG. 10 is a cross-sectional view taken along line IV-IV of FIG. 3 in the fifth modification (cross-sectional view corresponding to FIG. 4).

Similarly to the above-described insulating material 40, an insulating material 90 shown in FIGS. 9 and 10 integrally has a bottom portion 91 and sidewalls 92 and 93 facing each other. The bottom portion 91 is provided with a fin side protrusion portion 91a protruding toward the plurality of heat dissipation fins 32. The fin side protrusion portion 91a can be provided at any position, and in the example of FIG. 10, the fin side protrusion portion 91a is provided at the center of the bottom portion 91 in the X direction and the Y direction. The fin side protrusion portion 91a has a rectangular shape in plan view (see FIG. 10), but may have another shape such as a circular shape.

The fin side protrusion portion 91a is inserted into a recess portion 32b of the plurality of heat dissipation fins 32. The recess portion 32b is formed by shortening the length of at least one heat dissipation fin 32 (in FIG. 10, a heat dissipation fin 32 hatched in the opposite direction to other heat dissipation fins 32) facing the fin side protrusion portion 91a. The fin side protrusion portion 91a is inserted into the recess portion 32b. Desirably, the fin side protrusion portion 91a is fitted into the recess portion 32b of the plurality of heat dissipation fins 32.

A fin side recess portion may be provided in the insulating material 90, and a protrusion portion that is inserted into the fin side recess portion may be provided in the plurality of heat dissipation fins 32. In this case, the protrusion portion of the plurality of heat dissipation fins 32 may be provided, for example, by at least one heat dissipation fin 32 extending longer than other heat dissipation fins 32 in the negative Z direction.

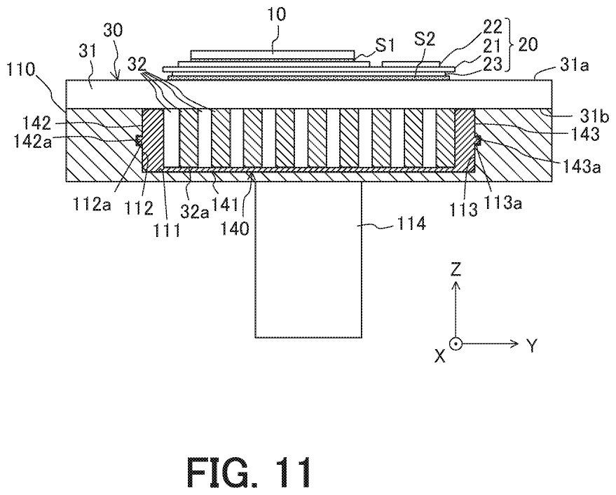

FIG. 11 is a right side view of a semiconductor device showing an internal structure of a water jacket 110 in a sixth modification.

Recess portions 112a and 113a provided on the insulating material 140 side are provided on the side surfaces 112 and 113 of the water jacket 110.

Similarly to the above-described insulating material 40, an insulating material 140 integrally has a bottom portion 141 and sidewalls 142 and 143 facing each other. The sidewalls 142 and 143 are provided with jacket side protrusion portions 142a and 143a that protrude to a side opposite to the heat dissipation fins 32 and are inserted into the recess portions 112a and 113a of the side surfaces 112 and 113, respectively. Desirably, the jacket side protrusion portions 142a and 143a are fitted into the recess portions 112a and 113a of the side surfaces 112 and 113, respectively.

The jacket side protrusion portions 142a and 143a of the sidewalls 142 and 143 of the insulating material 140 may be provided only on a part of the insulating material 140 in the X direction and the Z direction. In addition, the jacket side protrusion portions 142a and 143a of the insulating material 140 may be provided on only one of the sidewalls 142 and 143 or on the bottom portion 141. In this case, the recess portions 112a and 113a of the water jacket 110 are also provided on only one of the side surfaces 112 and 113 or on the bottom surface 111.

In addition, a protrusion portion may be provided in the water jacket 110, and a jacket side recess portion that is recessed toward the heat dissipation fins 32 and inserted into the protrusion portion of the water jacket 110 may be provided in the insulating material 140.

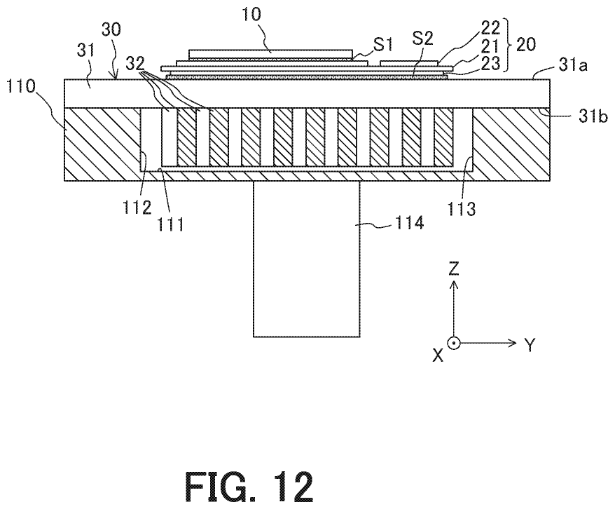

As shown in FIGS. 12 to 14, in a state in which the insulating material 40 shown in FIGS. 1 to 4 is removed, the water flow resistance of the clearance between the plurality of heat dissipation fins 32 and the water jacket 110 (the bottom surface 111 and the side surfaces 112 and 113) is small. Accordingly, when the cooling water W flows through the clearance, the flow rate (flow velocity) of the cooling water W passing between the heat dissipation fins 32 is relatively reduced, and the cooling performance cannot be sufficiently exhibited. Therefore, if a structure in which the cooling water W hardly flows through the clearance or high-accuracy processing for reducing tolerance is adopted, costs increase.

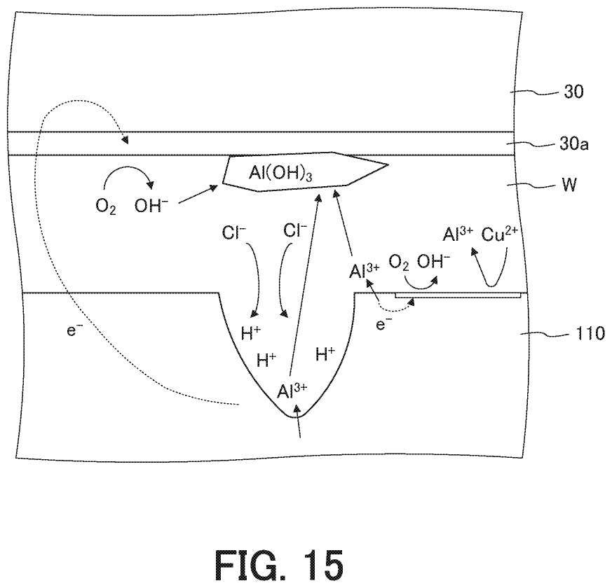

In the clearance between the plurality of heat dissipation fins 32 and the water jacket 110, in a case where the plurality of heat dissipation fins 32 (coolers 30) are made of a copper material and the water jacket 110 is made of a die-casting material, a local battery due to a potential difference between the dissimilar metals is formed in a state in which the heat dissipation fins 32 and the water jacket 110 are close to each other with the cooling water W filling the space therebetween, and a corrosion product such as aluminum hydroxide (Al(OH)₃) shown in FIG. 15 is generated.

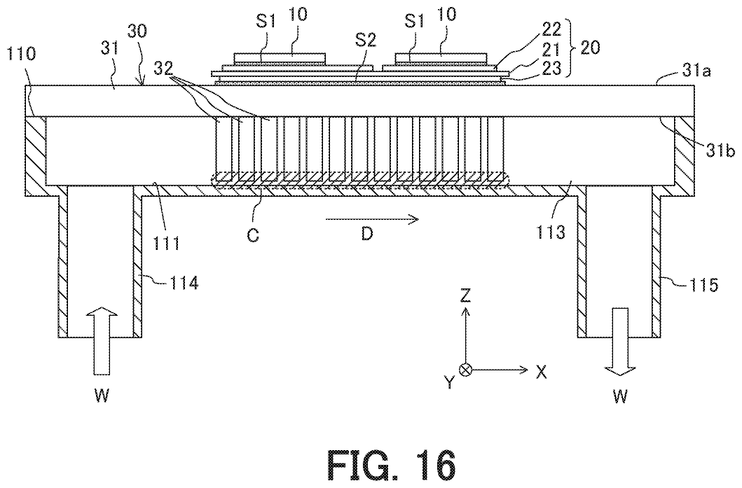

As shown in FIG. 15, the cooler 30 is subjected to, for example, nickel plating 30a. The water jacket 110 made of aluminum having a relatively large ionization tendency acts as an anode and emits electrons e⁻, and aluminum ions Al³⁺ are melted out (anode reaction). In addition, the cooler 30 made of copper having a relatively small ionization tendency receives the electrons e⁻ emitted as a cathode. By a cathode reaction of the electrons e⁻, oxygen O₂, and water H₂O of the cooling water W, hydroxide ions OH⁻ are generated (cathode reaction). Then, a corrosion product such as aluminum hydroxide (Al(OH)₃) is generated. Such a corrosion product generated particularly by corrosion of the water jacket 110 adheres between the plurality of heat dissipation fins 32 and between the plurality of heat dissipation fins 32 and the water jacket 110 as in a corroded portion C indicated by the broken lines in FIG. 16. In addition, pitting corrosion locally occurs in the water jacket 110 due to corrosion of the water jacket 110.

In the present embodiment described above, the semiconductor module 1 includes the semiconductor element 10, the stacked substrate 20 that is an example of a substrate, the cooler 30, and the insulating material 40. The semiconductor element 10 is mounted on the stacked substrate 20. The cooler 30 includes the heat dissipation base 31 and the plurality of heat dissipation fins 32 positioned on a side opposite to the stacked substrate 20 from the heat dissipation base 31, and is attached to the water jacket 110 for allowing the cooling water W to flow through the plurality of heat dissipation fins 32. The insulating material 40 integrally has the bottom portion 41 that extends along the flow direction D in which the cooling water W flows through the plurality of heat dissipation fins 32, and is disposed to face at least some of the tips 32a of the plurality of heat dissipation fins 32, and the sidewalls 42 and 43 that extend from the bottom portion 41 toward the heat dissipation base 31, and are disposed in at least some of the plurality of heat dissipation fins 32.

In the present embodiment, the semiconductor device 100 includes the semiconductor module 1 and the water jacket 110.

In the semiconductor module 1 and the semiconductor device 100, the insulating material 40 is disposed in a clearance provided between the plurality of heat dissipation fins 32 and the water jacket 110 so as not to come into contact with each other due to variations in dimensions at the time of manufacture. Therefore, the clearance between the plurality of heat dissipation fins 32 and the water jacket 110 is filled with the insulating material 40, so that the cooling water W easily passes between the plurality of heat dissipation fins 32 and the cooling performance can be improved. In addition, since the insulating material 40 is disposed between the plurality of heat dissipation fins 32 and the water jacket 110, it is possible to suppress formation of a local battery due to a potential difference. Therefore, it is possible to suppress corrosion of the water jacket 110 and the plurality of heat dissipation fins 32, and occurrence of deterioration in cooling performance and pressure loss due to the deposited corrosion product clogging the spaces between the plurality of heat dissipation fins 32. Furthermore, in the insulating material 40, at least one of the sidewalls 42 and 43 is integrated with the bottom portion 41. Therefore, the insulating material 40 can be disposed along the bottom surface 111 and the side surfaces 112 and 113 of the water jacket 110 or along the tips 32a and the side surfaces of the heat dissipation fins 32, and thus it is possible to make fixing and positioning of the insulating material 40 inside the water jacket 110 easy. Therefore, according to the present embodiment, it is possible to make assembly easy while improving cooling performance and preventing corrosion. Furthermore, the semiconductor module 1 and the semiconductor device 100 can have a simpler configuration than in a case where the insulating material 40 is separated from the bottom portion 41 and the sidewalls 42 and 43. In addition, the shape of the insulating material 40 integrally having the bottom portion 41 and the sidewalls 42 and 43 is easy to mold. In addition, by improving the cooling performance (heat dissipation performance) as described above, it is possible to improve the output of the semiconductor module 1 and reduce the size thereof, to reduce the cost of the chip shrink, and to improve reliability by suppressing the heat generation temperature. In addition, since a design can be made without concern about contact between the heat dissipation fins 32 and the bottom surface 111 of the water jacket 110 and formation of a local battery due to the contact, it is also possible to alleviate tolerance requirements regarding flatness of the heat dissipation fins 32 and the water jacket 110.

In the present embodiment, the sidewalls 42 and 43 of the insulating material 40 face each other, and the plurality of heat dissipation fins 32 are surrounded by the bottom portion 41 and the sidewalls 42 and 43.

Therefore, since the insulating material 40 is disposed in the clearance between the plurality of heat dissipation fins 32 and the bottom surface 111 and the side surfaces 112 and 113 of the water jacket 110, it is possible to improve cooling performance and prevent corrosion on all of the bottom surface 111, the side surface 112, and the side surface 113. In addition, since the insulating material 40 can be disposed along the inside of the water jacket 110, it is possible to make it even easier to assemble the insulating material 40 inside the water jacket 110. Furthermore, it is also possible to make the configuration even simpler than in a case where the insulating material 40 is separated from the bottom portion 41 and the two sidewalls 42 and 43.

In the first modification (FIG. 5A) and the third modification (FIG. 7) of the present embodiment, the bottom portions 51 and 71 of the insulating materials 50 and 70 are positioned to face the tips 32a of only some heat dissipation fins 32 on the downstream side in the flow direction D among the plurality of heat dissipation fins 32.

Therefore, when the cooling water W passes through the heat dissipation fins 32 on the downstream side on which the cooling water W is more likely to become hotter than when passing through the heat dissipation fins 32 on the upstream side in the flow direction D, the cooling water W hardly flows through the clearance between the heat dissipation fins 32 and the bottom surface 111 of the water jacket 110. Therefore, the heat dissipation performance of the heat dissipation fins 32 on the downstream side can be made close to that of the heat dissipation fins 32 on the upstream side in the flow direction D.

In the first modification (FIG. 5A) and the second modification (FIG. 6) of the present embodiment, the sidewalls 52 and 62 of the insulating materials 50 and 60 are positioned to face only some heat dissipation fins 32 on the downstream side in the flow direction D among the plurality of heat dissipation fins 32.

Therefore, when the cooling water W passes through the heat dissipation fins 32 on the downstream side on which the cooling water W is more likely to become hotter than when passing through the heat dissipation fins 32 on the upstream side in the flow direction D, the cooling water W hardly flows through the clearance between the heat dissipation fins 32 and the side surfaces 112 and 113 of the water jacket 110. Therefore, the heat dissipation performance of the heat dissipation fins 32 on the downstream side can be made close to that of the heat dissipation fins 32 on the upstream side in the flow direction D.

In addition, in the fourth modification (FIG. 8) and the fifth modification (FIGS. 9 and 10) of the present embodiment, the plurality of heat dissipation fins 32 include at least one of the recess portion 32b (or the recess portion formed by the lack of one heat dissipation fin 32) into which the fin side protrusion portions 83a and 91a provided in the insulating materials 80 and 90 are inserted, and the protrusion portion that is inserted into the fin side recess portions provided in the insulating materials 80 and 90.

Therefore, since the insulating materials 80 and 90 can be positioned with respect to the heat dissipation fins 32, it is possible to make it even easier to assemble the insulating materials 80 and 90 inside the water jacket 110. In addition, it is possible to suppress positional displacement of the insulating material 40 due to the water pressure when the cooling water W flows.

In addition, in the sixth modification (FIG. 11) of the present embodiment, the insulating material 140 includes at least one of the jacket side protrusion portions 142a and 143a that are inserted into the recess portion 112a provided in the water jacket 110, and the jacket side recess portion into which the protrusion portion provided in the water jacket 110 is inserted.

Therefore, since the insulating material 140 can be directly positioned in the water jacket 110, it is possible to make it even easier to assemble the insulating material 140 inside the water jacket 110. In addition, it is possible to suppress positional displacement of the insulating material 40 due to the water pressure when the cooling water W flows.

Hereinafter, some inventions described in the specification and drawings of the present application will be additionally described.

### Supplementary Note 1

A semiconductor module including:
a semiconductor element;
a substrate on which the semiconductor element is mounted;
a cooler that has a heat dissipation base and a plurality of heat dissipation fins positioned on a side opposite to the substrate from the heat dissipation base, and is attached to a water jacket for allowing cooling water to flow through the plurality of heat dissipation fins; and
an insulating material integrally having a bottom portion that extends along a flow direction in which the cooling water flows through the plurality of heat dissipation fins, and faces at least some of tips of the plurality of heat dissipation fins, and a sidewall that extends from the bottom portion toward the heat dissipation base, and faces at least some of the heat dissipation fins.

### Supplementary Note 2

The semiconductor module according to supplementary note 1,
in which the sidewall of the insulating material has a first sidewall and a second sidewall disposed to face the first sidewall, and
the plurality of heat dissipation fins are surrounded by the bottom portion, the first sidewall, and the second sidewall in side view.

### Supplementary Note 3

The semiconductor module according to supplementary note 1 or 2,
in which the bottom portion of the insulating material is positioned to face the tips of only some heat dissipation fins on a downstream side in the flow direction among the plurality of heat dissipation fins.

### Supplementary Note 4

The semiconductor module according to any one of supplementary notes 1 to 3,
in which the sidewall of the insulating material is positioned to face only some heat dissipation fins on a downstream side in the flow direction among the plurality of heat dissipation fins.

### Supplementary Note 5

The semiconductor module according to any one of supplementary notes 1 to 4,
in which the plurality of heat dissipation fins include at least one of a recess portion into which a fin side protrusion portion provided in the insulating material is inserted, and a protrusion portion that is inserted into a fin side recess portion provided in the insulating material.

### Supplementary Note 6

The semiconductor module according to supplementary note 1,
in which the insulating material includes at least one of a jacket side protrusion portion protruding toward a side opposite to the heat dissipation fins, and a jacket side recess portion recessed toward the heat dissipation fins.

### Supplementary Note 7

The semiconductor module according to supplementary note 1,
in which the bottom portion of the insulating material has a size equal to or larger than that of a region where the plurality of heat dissipation fins are disposed.

### Supplementary Note 8

The semiconductor module according to supplementary note 1,
in which the sidewall of the insulating material has a size equal to or larger than that of a region where the plurality of heat dissipation fins are disposed in the flow direction among the plurality of heat dissipation fins.

### Supplementary Note 9

A semiconductor device including:
the semiconductor module according to any one of supplementary notes 1 to 8; and
the water jacket.

### Supplementary Note 10

The semiconductor device according to supplementary note 9,
in which the water jacket has a bottom surface on which the bottom portion of the insulating material is disposed, and a side surface on which the sidewall of the insulating material is disposed.

### INDUSTRIAL APPLICABILITY

As described above, the present invention is effective to make assembly easy while improving cooling performance and preventing corrosion in a semiconductor module and a semiconductor device, and is particularly useful for an industrial or electrical inverter device.

The present application is based on Japanese Patent Application No. 2024-069640 filed on Apr. 23, 2024. All the contents are included herein.

### REFERENCE SIGNS LIST

1 Semiconductor module
10 Semiconductor element
20 Stacked substrate (substrate)
21 Insulating plate
22 Circuit board
23 Heat dissipation plate
30 Cooler
30a Nickel plating
31 Heat dissipation base
31a Upper surface
31b Lower surface
32 Heat dissipation fin
32a Tip
32b Recess portion
40, 50, 60, 70, 80, 90, 140 Insulating material
41, 51, 61, 71, 81, 91, 141 Bottom portion
42, 43, 52, 53, 62, 63, 72, 73, 82, 83, 92, 93, 142, 143 Sidewall
83a, 91a Fin side protrusion portion
142a, 143a Jacket side protrusion portion
100 Semiconductor device
110 Water jacket
111 Bottom surface
112, 113 Side surface
112a, 113a Recess portion
114 Introduction pipe
115 Discharge pipe
C Corroded portion
D Flow direction
S1, S2 Bonding material
W Cooling water

1. A semiconductor module for use in a semiconductor device having a water jacket, the semiconductor module comprising:
a substrate;
a semiconductor element mounted on the substrate;
a cooler that has
a heat dissipation base, and
a plurality of heat dissipation fins positioned on the heat dissipation base, on a side thereof opposite to the substrate,
the cooler being configured to be attached to the water jacket for allowing cooling water to flow in a flow direction through the plurality of heat dissipation fins; and
an insulating material integrally forming
a bottom portion that extends along the flow direction, and faces tips of at least a first subset of the plurality of heat dissipation fins, and
a sidewall that extends from the bottom portion toward the heat dissipation base, and faces at least a second subset of the plurality of heat dissipation fins.

2. The semiconductor module according to claim 1,
wherein the sidewall of the insulating material has a first sidewall and a second sidewall facing each other, and
the plurality of heat dissipation fins are surrounded by the bottom portion, the first sidewall, and the second sidewall in a side view of the semiconductor module.

3. The semiconductor module according to claim 1,
wherein the first subset of the plurality of heat dissipation fins is on a downstream side, with respect to the flow direction, of the plurality of heat dissipation fins.

4. The semiconductor module according to claim 1,
wherein the second subset of the plurality of heat dissipation fins is on a downstream side, with respect to the flow direction, of the plurality of heat dissipation fins.

5. The semiconductor module according to claim 1, wherein
the insulating material further forms a fin side protrusion portion or a fin side recess portion, and
the plurality of heat dissipation fins include at least one of
a recess portion into which the fin side protrusion portion is inserted, and
a protrusion portion that is inserted into the fin side recess portion.

6. The semiconductor module according to claim 1,
wherein the insulating material further forms at least one of
a jacket side protrusion portion protruding toward a side of the side wall opposite to the heat dissipation fins, and
a jacket side recess portion recessed into the side wall toward the heat dissipation fins.

7. The semiconductor module according to claim 1,
wherein the bottom portion of the insulating material has a size equal to or larger than that of a region of the heat dissipation base in which the plurality of heat dissipation fins are disposed.

8. The semiconductor module according to claim 1,
wherein the sidewall of the insulating material fully covers the plurality of heat dissipation fins in a side view along the flow direction.

9. A semiconductor device comprising:
the semiconductor module according to claim 1; and
the water jacket.

10. The semiconductor device according to claim 9,
wherein the water jacket has
a bottom surface on which the bottom portion of the insulating material is disposed, and
a side surface on which the sidewall of the insulating material is disposed.
